(19) United States
(12) Patent Application Publication
(10) Pub. No.: US 2017/0207077 A1
(43) Pub. Date: Jul. 20, 2017

(54) Variable Pattern Separation Grid for Plasma Chamber

(71) Applicant: Mattson Technology, Inc., Fremont, CA (US)

(72) Inventors: Vladimir Nagorny, Tracy, CA (US); Shawming Ma, Sunnyvale, CA (US); Vijay M. Vaniapura, Tracy, CA (US); Ryan M. Pakulski, Discovery Bay, CA (US)

(21) Appl. No.: 15/403,455

(22) Filed: Jan. 11, 2017

Related U.S. Application Data
(60) Provisional application No. 62/279,162, filed on Jan. 15, 2016.

(51) Int. Cl. H01L 21/02; H01L 21/027; B08B 7/00; H01J 37/32

(52) U.S. Cl. CPC H01L 21/0206; H01J 37/32009; H01L 21/0273; B08B 7/0035; H01J 2237/334

(57) ABSTRACT

Systems, methods, and apparatus for processing a substrate in a plasma processing apparatus using a variable pattern separation grid are provided. In one example implementation, a plasma processing apparatus can have a plasma chamber and a processing chamber separated from the plasma chamber. The apparatus can further include a variable pattern separation grid separating the plasma chamber and the processing chamber. The variable pattern separation grid can include a plurality grid plates. Each grid plate can have a grid pattern with one or more holes. At least one of the plurality of grid plates is movable relative to the other grid plates in the plurality of grid plates such that the variable pattern separation grid can provide a plurality of different composite grid patterns.

### PRIORITY CLAIM

The present application claims the benefit of priority of U.S. Provisional Patent Application Ser. No. 62/279,162, filed Jan. 15, 2016, titled “Variable Pattern Separation Grid for Plasma Chamber,” which is incorporated herein by reference.

### FIELD

The present disclosure relates generally to apparatus, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates.

For a photoresist strip (e.g., dry clean) removal process, it can be undesirable to have direct plasma interaction with a substrate. Rather, plasma can be used mainly as an intermediate for modification of a gas composition and creating chemically active radicals for processing the substrates. Accordingly, plasma processing apparatus for photoresist application can include a processing chamber where the substrate is processed that is separated from a plasma chamber where plasma is generated.

In some applications, a grid can be used to separate a processing chamber from a plasma chamber. The grid can be transparent to neutral species but not transparent to charged particles from the plasma. The grid can include a sheet of material with holes. Depending on the process, the grid can be made of a conductive material (e.g., Al, Si, SiC, etc.) or non-conductive material (e.g., quartz, etc.).

FIG. 1 depicts an example separation grid 10 that can be used to separate a processing chamber from a plasma chamber. As illustrated the separation grid 10 can include a plurality of holes 12 that allow the passage of neutral species from the plasma chamber to the processing chamber.

In some applications, ultraviolet (UV) radiation coming from the plasma may need to be blocked to reduce damage to features on the wafer. In these applications, a dual grid can be used. The dual grid can include two single grids (e.g., top and bottom) with holes distributed in special patterns on each of them, so that there is no direct line of sight between the plasma chamber and the processing chamber.

A grid pattern for the separation grid can be an effective way of controlling the process profile across a wafer in a plasma process. Other process parameters, (e.g., gas flow, pressure, etc.) can be used for fine tuning of the process profile. Because of that large influence of the process chemistry on the process profile across the wafer, separation grids are typically compatible only with the process chemistry for which the separation grid is designed. If a different process needs to be performed, the separation grid of the plasma processing chamber may have to be changed.

Changing grids can be an expensive and long procedure and can require, for instance, opening the processing chamber. Opening the processing chamber can break the vacuum in the processing chamber and can expose the processing chamber to an atmosphere. After the processing chamber has been exposed to the atmosphere, it typically has to be reconditioned again. Reconditioning can require processing many wafers using a plasma until all air contaminants are removed and walls in both the plasma chamber and the processing chamber reach suitable process conditions. In addition, the process flow for processing the wafers may have to be interrupted, leading to expensive downtime.

Because of this difficulty, many manufacturers avoid changing grids by dedicating process chambers to specific processes, each with its own specially tailored separation grid. If a wafer needs to be subjected to a different process, the wafer can be sent to a different processing chamber. This can be inconvenient and can complicate the flow of the manufacturing process.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus having a plasma chamber and a processing chamber separated from the plasma chamber. The apparatus can further include a variable pattern separation grid separating the plasma chamber and the processing chamber. The variable pattern separation grid can include a plurality grid plates. Each grid plate can have a grid pattern with one or more holes. At least one of the plurality of grid plates is movable relative to the other grid plates in the plurality of grid plates such that the variable pattern separation grid can provide a plurality of different composite grid patterns.

Another example aspect of the present disclosure is directed to a separation grid for a plasma processing apparatus. The separation grid includes a first grid plate having a first grid pattern and a second grid plate in spaced parallel relationship with the first grid plate. The second grid plate has a second grid pattern. The second grid plate is movable relative to the first grid plate such that when the second grid plate is in a first position relative to the first grid plate, the separation grid provides a first composite grid pattern. When the second grid plate is in a second position, the separation grid provides a second composite grid pattern. The second composite grid pattern is different from the first composite grid pattern.

Another example aspect of the present disclosure is directed to a method of processing a substrate in a plasma processing apparatus. The method includes receiving a first substrate in a processing chamber separated from a plasma chamber by a variable pattern separation grid. The variable pattern separation grid includes a first grid plate having a first grid pattern and a second grid plate in spaced parallel relationship with the first grid plate. The second grid plate can have a second grid pattern. The method can include adjusting a position of the second grid plate relative to the first grid plate to adjust a composite grid pattern associated with the variable pattern separation grid from a first composite grid pattern to a second composite grid pattern. The second composite grid pattern is different from the first composite grid pattern. The method can include processing the first substrate in the processing chamber using neutral species passing from the plasma chamber to the processing chamber through the variable pattern separation grid.

Other example aspects of the present disclosure are directed to systems, methods, devices, and processes for plasma processing a substrate using a variable pattern separation grid.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example separation grid that can be used in a plasma processing apparatus;

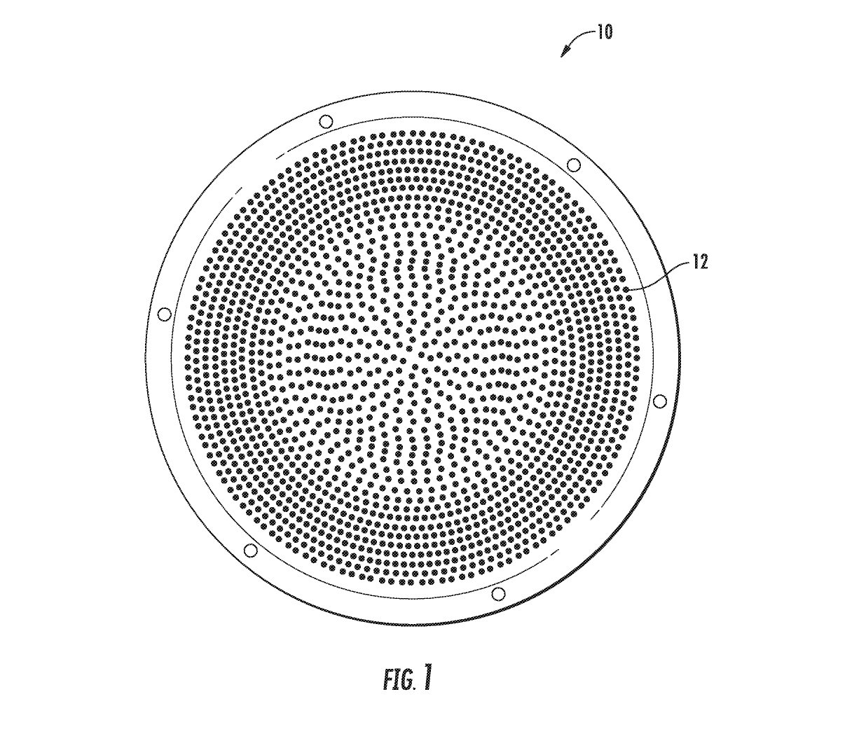

FIG. 2 depicts a plasma processing apparatus according to example embodiments of the present disclosure;

FIG. 3 depicts a cross-sectional view of a variable pattern separation grid according to example embodiments of the present disclosure;

FIGS. 4A to 4C depict the example generation of composite grid patterns using a variable pattern separation grid according to example embodiments of the present disclosure;

FIGS. 5A to 5B depict the example generation of composite grid patterns using a variable pattern separation grid according to example embodiments of the present disclosure;

FIGS. 6 and 7 depict example grid patterns on a first grid plate and a second grid plate according to example embodiments of the present disclosure;

FIGS. 8A to 8D depict the example generation of composite grid patterns using a variable pattern separation grid according to example embodiments of the present disclosure;

FIG. 9 depicts example grid patterns on a first grid plate and a second grid plate according to example embodiments of the present disclosure;

FIGS. 10A to 10B depict the example generation of composite grid patterns using a variable pattern separation grid according to example embodiments of the present disclosure; and

FIG. 11 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to a variable pattern charge separation grid for a plasma processing chamber for processing substrates, such as semiconductor wafers. Aspects of the present disclosure are discussed with reference to a “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within 30% of the stated numerical value.

In some embodiments, a plasma processing apparatus can include a variable pattern separation grid that can allow for changing of the grid pattern to be tailored to a specific process and/or to achieve a desired process profile across the substrate. The variable pattern separation grid can include a plurality of parallel grid plates each with its own grid pattern. Each of the plurality of grid plates can be moved relative to one another to create an overall desired composite grid pattern. For instance, the plurality of grid plates can be moved relative to one another to create a center dense composite grid pattern, an edge dense composite grid pattern, a dual grid composite grid pattern for blocking UV light, or other composite grid pattern. The composite grid pattern refers to the effective grid pattern generated by the plurality of grid plates in the variable pattern separation grid. In this way, the variable pattern separation grid according to example embodiments of the present disclosure can provide for the changing of a grid pattern of a separation grid in a plasma processing apparatus without requiring opening of the processing chamber, providing huge cost and efficiency benefits in the processing of substrates, such as semiconductor wafers.

One example embodiment of the present disclosure is directed to a plasma processing apparatus. The apparatus can include a plasma chamber. The apparatus can include a processing chamber separated from the plasma chamber. The apparatus can include a variable pattern separation grid separating the plasma chamber and the processing chamber. The variable pattern separation grid can include a plurality of grid plates. Each grid plate can include a grid pattern with one or more holes. At least one of the grid plates is movable relative to another grid plate in the plurality of grid plates such that variable pattern separation grid can provide a plurality of different composite grid patterns. In some embodiments, the plurality of different composite grid patterns include, for instance, one or more of a sparse composite grid pattern, a dense composite grid pattern, and/or a dual grid composite grid plasma.

Variations and modifications can be made to this example embodiment. For instance, in some embodiments, the plurality of grid plates can include a first grid plate and a second grid plate. The second grid plate can be movable relative to the first grid plate. When the second grid plate is in a first position, the variable pattern separation grid can provide a first composite grid pattern. When the second grid plate is in a second position, the variable pattern separation grid can provide a second composite grid pattern. In some embodiments, the first composite grid pattern can have a first hole density and the second composite grid pattern can include a second hole density that is different from the first hole density. In some embodiments, the second composite grid pattern can be a dual grid composite pattern configured to block UV light.

In some embodiments, in the first composite grid pattern, a first portion of the variable pattern separation grid has a first hole density and a second portion of the variable pattern separation grid has a second hole density. The second hole density is different from the first hole density. In some embodiments, in the second composite grid pattern, the first portion of the variable pattern separation grid has a third hole density that is different from the first hole density and the second portion of the variable pattern separation grid has a fourth hole density that is different from the second hole density.

In some embodiments, the second grid plate is movable relative to the first grid plate in one or more of three-dimensions. In some embodiments, the second grid plate is coupled to a manipulator configured to move the second grid plate relative to the first grid plate. In some embodiments, one or more of the first grid plate and the second grid plate are electrically conductive. In some embodiments, one or more of the first grid plate and the second grid plate are grounded.

Another example embodiment of the present disclosure is directed to a separation grid for a plasma processing apparatus. The separation grid includes a first grid plate having a first grid pattern and a second grid plate in spaced parallel relationship with the first grid plate. The second grid plate has a second grid pattern. The second grid plate is movable relative to the first grid plate such that when the second grid plate is in a first position relative to the first grid plate, the separation grid provides a first composite grid pattern. When the second grid plate is in a second position, the separation grid provides a second composite grid pattern. The second composite grid pattern is different from the first composite grid pattern.

Variations and modifications can be made to this example embodiment. For instance, in some embodiments, the first composite grid pattern can be a sparse composite grid pattern and the second composite grid pattern can be a dense composite grid pattern that has a greater hole density relative to the sparse composite grid pattern. In some embodiments, the second composite grid pattern is a dual grid composite grid pattern for blocking UV light.

In some embodiments, in the first composite grid pattern, a first portion of the variable pattern separation grid has a first hole density and a second portion of the variable pattern separation grid has a second hole density. The second hole density is different from the first hole density. In some embodiments, in the second composite grid pattern, the first portion of the variable pattern separation grid has a third hole density that is different from the first hole density and the second portion of the variable pattern separation grid has a fourth hole density that is different from the second hole density.

Another example embodiment of the present disclosure is directed to a method of processing a substrate in a plasma processing apparatus. The method includes receiving a first substrate in a processing chamber separated from a plasma chamber by a variable pattern separation grid. The variable pattern separation grid includes a first grid plate having a first grid pattern and a second grid plate in spaced parallel relationship with the first grid plate. The second grid plate can have a second grid pattern. The method can include adjusting a position of the second grid plate relative to the first grid plate to adjust a composite grid pattern associated with the variable pattern separation grid from a first composite grid pattern to a second composite grid pattern. The second composite grid pattern is different from the first composite grid pattern. The method can include processing the first substrate in the processing chamber using neutral species passing from the plasma chamber to the processing chamber through the variable pattern separation grid.

Variations and modifications can be made to this example embodiment. For instance, in some embodiments, the method can include receiving a second substrate in the processing chamber; adjusting a position of the second grid plate relative to the first grid plate to adjust the composite grid patter associated with the variable pattern separation grid from the second composite grid pattern to the first composite grid pattern; and processing the second substrate in the processing chamber using neutral species passing from the plasma chamber to the processing chamber through the variable pattern separation grid. In some embodiments, the first composite grid pattern can be a sparse composite grid pattern and the second composite grid pattern can be a dense composite grid pattern that has a greater hole density relative to the sparse composite grid pattern.

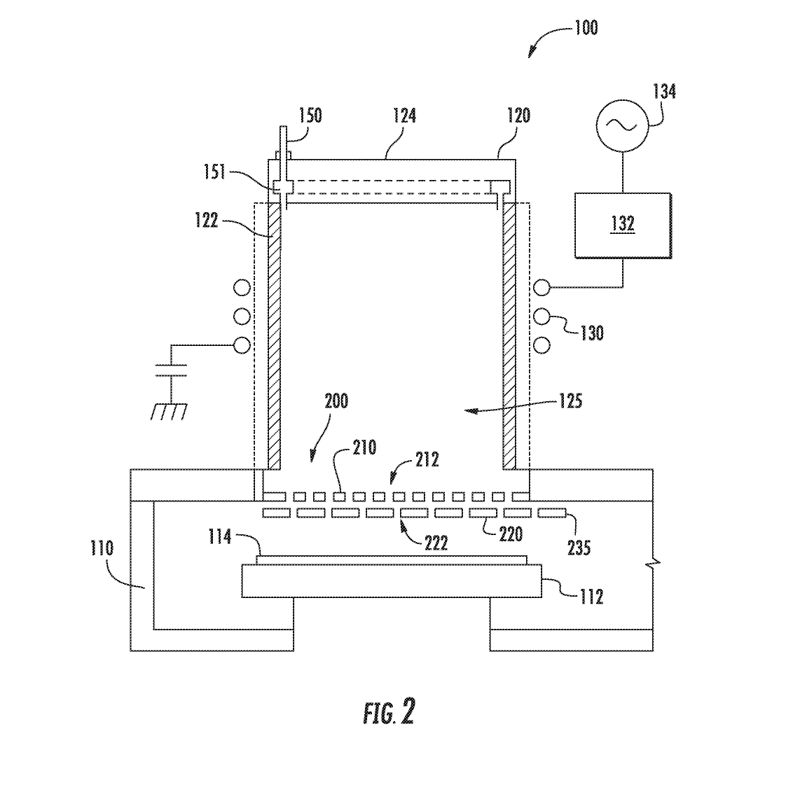

FIG. 2 depicts a plasma processing apparatus according to example embodiments of the present disclosure. As illustrated, plasma processing apparatus 100 includes a processing chamber 110 and a plasma chamber 120 that is separate from the processing chamber 110. Processing chamber 110 includes a substrate holder or pedestal 112 operable to hold a substrate 114 to be processed, such as a semiconductor wafer. In this example illustration, a plasma is generated in plasma chamber 120 (i.e., plasma generation region) by an inductive plasma source and desired particles are channeled from the plasma chamber 120 to the surface of substrate 114 through a variable pattern separation grid 200 according to example embodiments of the present disclosure.

The plasma chamber 120 includes a dielectric side wall 122 and a ceiling 124. The dielectric side wall 122, ceiling 124, and grid 200 define a plasma chamber interior 125. Dielectric side wall 122 can be formed from any dielectric material, such as quartz. An induction coil 130 is disposed adjacent the dielectric side wall 122 about the plasma chamber 120. The induction coil 130 is coupled to an RF power generator 134 through a suitable matching network 132. Reactant and carrier gases can be provided to the chamber interior from gas supply 150 and annular gas distribution channel 151 or other suitable gas introduction mechanism. When the induction coil 130 is energized with RF power from the RF power generator 134, a plasma is generated in the plasma chamber 120. In a particular embodiment, the plasma reactor 100 can include an optional faraday shield 128 to reduce capacitive coupling of the induction coil 130 to the plasma.

As shown in FIG. 2, the variable pattern separation grid 200 can include a first grid plate 210 and a second grid plate 220 that are spaced apart in parallel relationship to one another. The first grid plate 210 and the second grid plate can be separated by a distance. The first grid plate 210 can have a first grid pattern 212 having a plurality of holes. The second grid plate 220 can have a second grid pattern 222 having a plurality of holes. The first grid pattern 212 can be the same as or different from the second grid pattern 222. Charged particles can recombine on the walls in their path through the holes of each grid plate 210, 220 in the variable pattern separation grid 200. Neutral species can flow relatively freely through the holes in the first grid plate 210 and the second grid plate 220. The size of the holes and thickness of each grid plate 210 and 220 can affect transparency for both charged and neutral particles, but can affect charged particles more strongly.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate made of metal or other electrically conductive material, the grid plate can be grounded.

The first grid plate 210 and the second grid plate 220 can be configured to move relative to one another. For instance, in one example embodiment, the first grid plate 210 can be secured or attached to a wall of the processing chamber 110 and/or the plasma chamber 120. The second grid plate 220 can be spaced apart from the first grid plate 210 and secured to a manipulator 230. The manipulator 230 can be configured to move the second grid plate 220 in one or more of three-dimensions (e.g., along one or more of an x-axis, y-axis, and/or z-axis) relative to the first grid plate 210. The manipulator 230 can be any suitable device for moving the second grid plate 220 and can include, for instance, a motor, encoder, actuator, or other suitable device.

Example aspects of the present disclosure are discussed with reference to a variable pattern separation grid having two parallel grid plates for purposes of illustration and discussion. Those of ordinary skill in the art, using the disclosures provided herein, will understand that other quantities of grid plates can be used without deviating from the scope of the present disclosure, such as three grid plates, four grid plates, five grid plates, etc. In addition, the grid plates may be disposed in non-parallel arrangement with one another without deviating from the scope of the present disclosure.

In one example embodiment, the second grid plate 220 can be moved relative to the first grid plate 220 so that when the second grid plate 220 is in a first position, matching holes from the first grid plate 210 and the second grid plate 220 generate a composite grid pattern that may be dense in one area (e.g., dense in the center). When the second grid plate 220 is in a second position, matching holes from the first grid plate 210 and the second grid plate 220 can generate a composite grid pattern that may dense in another area (e.g., dense at the edge). In some embodiments, the second grid plate 220 can be moved to a third position to form another pattern and/or to form a dual grid for blocking UV light where at least a portion of the holes from the first grid 210 and the second grid 220 do not match up.

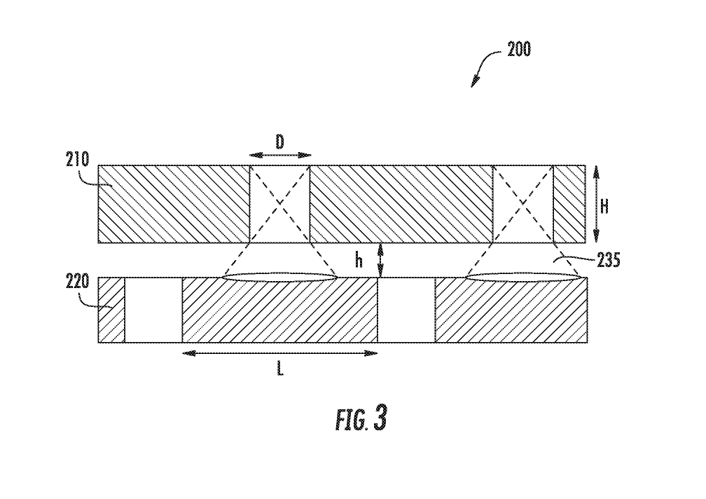

In one example implementation, each of the first grid 210 and the second grid 220 can have an identical grid pattern of holes (e.g., a triangular pattern, a square pattern, a hexagonal pattern, etc.). As shown in FIG. 3, the first grid plate 210 and the second grid plate 220 can be positioned relative to one another to form a dual grid composite grid pattern that prevents UV from penetrating through the variable pattern separation grid 200. In some embodiments, the size of the holes D in the grid plates 210 and 220 can be smaller than a distance between holes L in the grid plates to allow the holes to be shifted relative to one another without overlapping or partially overlapping holes in the other grid plate. In addition, the thickness H of each grid plate and the distance between the grid plates h can be selected to prevent the penetration of UV light through the variable pattern separation grid. As shown in FIG. 3, the thickness H of each grid plate, the size of holes D, the distance between grid plates h and the distance between holes L can be selected in such a way that UV light 235 is completely cut off by the second grid plate 220, while the gas flows almost freely.

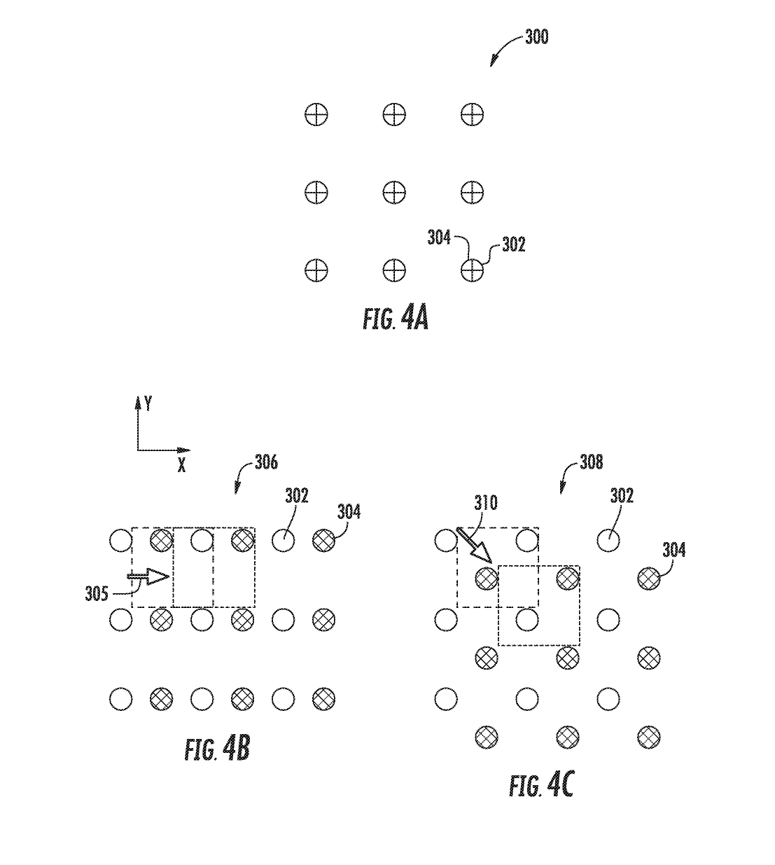

FIGS. 4A-4C depict the example formation of varying dual grid composite grid patterns using a variable pattern separation grid according to example embodiments of the present disclosure. More particular, FIG. 4A shows a composite grid pattern 300 that by can be formed by a variable pattern separation grid having a first grid plate and a second grid plate having identical grid patterns. The grid pattern on each grid plate can be a square grid pattern. In FIG. 4A, the second grid plate can be positioned relative the first grid plate such that holes 302 in the first grid plate match up or align with the holes in the second grid plate 304. The crosses depicted in the holes 302, 304 indicate that the holes 302, 304 overlap. This can form the square grid pattern shown in FIG. 4A.

In FIG. 4B, the second grid plate can be shifted incrementally relative to the first grid plate (or vice versa) along an x-direction as indicated by arrow 305 to form the dual grid pattern 306. As shown, the holes 302 in the first grid plate no longer match up with the holes 304 in the second grid plate, forming the dual grid pattern 306 shown in FIG. 4B. The holes 304 in the second grid plate are shaded in the figure to distinguish from holes 302 in the first grid plate.

Similarly, in FIG. 4C, the second grid plate can be shifted incrementally relative to the first grid plate (or vice versa) along an x-direction and a y-direction as indicated by arrow 310 to form a different dual grid pattern 308. As shown, the holes 302 in the first grid plate no longer match up with the holes 304 in the second grid plate, forming the dual grid pattern 308 shown in FIG. 4C. In this way, grid plates with identical grid patterns can be shifted incrementally relative to one another to form differing dual grid composite grid patterns.

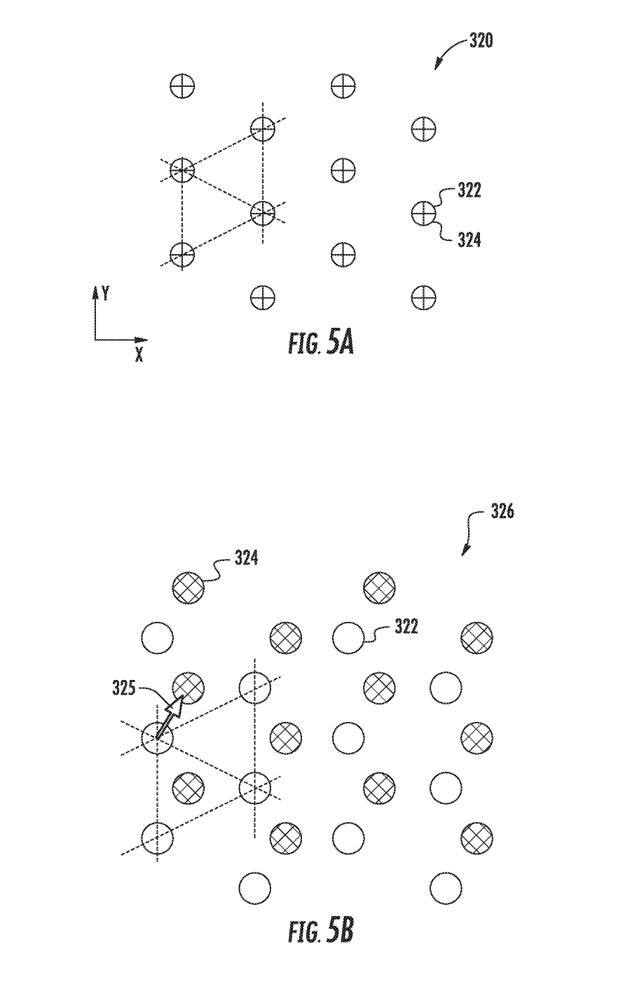

FIGS. 5A and 5B depict another example formation of varying grid patterns using a variable pattern separation grid according to example embodiments of the present disclosure. FIG. 5A shows a grid pattern 320 that by can be formed by a variable pattern separation grid having a first grid plate and a second grid plate with identical triangular grid patterns. The dashed line represents an example division of the grid pattern into triangular pattern elements.

In FIG. 5A, the second grid plate can be positioned relative the first grid plate such that holes 322 in the first grid plate match up or align with the holes in the second grid plate 324. The crosses depicted in the holes 322, 324 indicate that the holes 322, 324 overlap. This can form the triangular grid pattern shown in FIG. 5A.

In FIG. 5B, the second grid plate can be shifted incrementally relative to the first grid plate (or vice versa) along an x-direction and a y-direction as indicated by arrow 325 to form a dual grid pattern 326. As shown, the holes 322 in the first grid plate no longer match up with the holes 324 in the second grid plate, forming the dual grid pattern 326 shown in FIG. 5B. The holes 324 in the second grid plate are shaded in the figure to distinguish from holes 322 in the first grid plate. Various other grid patterns can be implemented on the first grid plate and the second grid plate without deviating from the scope of the present disclosure.

In some embodiments, the grid patterns on each of the parallel grid plates in the variable pattern separation grid can be subdivided into cells or other basic elements. Each cell can include one or more holes and one or more spaces with no holes. The one or more holes in each cell can form differing patterns having a first density, second density, etc. Depending on the shift of each cell in a grid plate relative to the other grid plate in the variable pattern separation grid, varying patterns of one or more densities and even dual grid patterns (e.g., zero density) can be generated using the variable pattern separation grid.

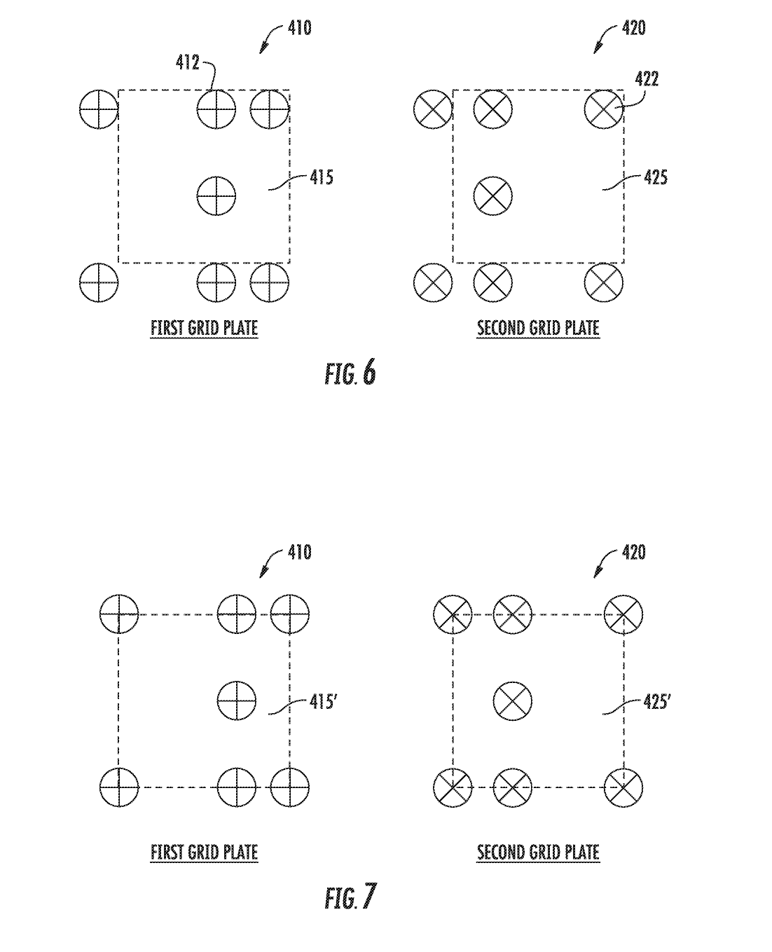

For example, FIG. 6 depicts one example division of grid patterns into cells. More particularly, a first grid plate can include a first grid pattern 410 and a second grid plate can include a second grid pattern 420. The first grid pattern 410 can be divided into cells, such as cell 415. Cell 415 includes holes 412 arranged in a particular pattern as well as spaces with no holes. Similarly, second grid pattern 420 can be divided into cells 420, such as cell 425. Cell 425 can include holes 422 arranged in a particular pattern as well as spaces with no holes. The size of cell 415 can be the same as the size of cell 425.

FIG. 7 depicts another example division of grid patterns into cells. More particularly, the first grid pattern 410 associated with the first grid plate is divided into larger cells, such as cell 415′. The hole pattern of cell 415′ is different from the hole pattern of cell 415 of FIG. 6. Similarly, as shown in FIG. 7, the second grid pattern 420 associated with the second grid plate is divided into larger cells, such as cell 425′. The hole pattern of cell 425′ is different from that of cell 425 of FIG. 6. The size of cell 415′ can be the same as the size of cell 425′.

As demonstrated by FIGS. 6 and 7, the grid patterns of the respective grid plates in the variable pattern separation grid can be divided into different cells in any suitable manner to achieve cells of varying hole densities and hole patterns within each cell. Shifting cells in the respective grid plates relative to one another can accomplish generating varying composite grid patterns, such as sparse grid patterns, dense grid patterns, dual grid patterns, and other grid patterns.

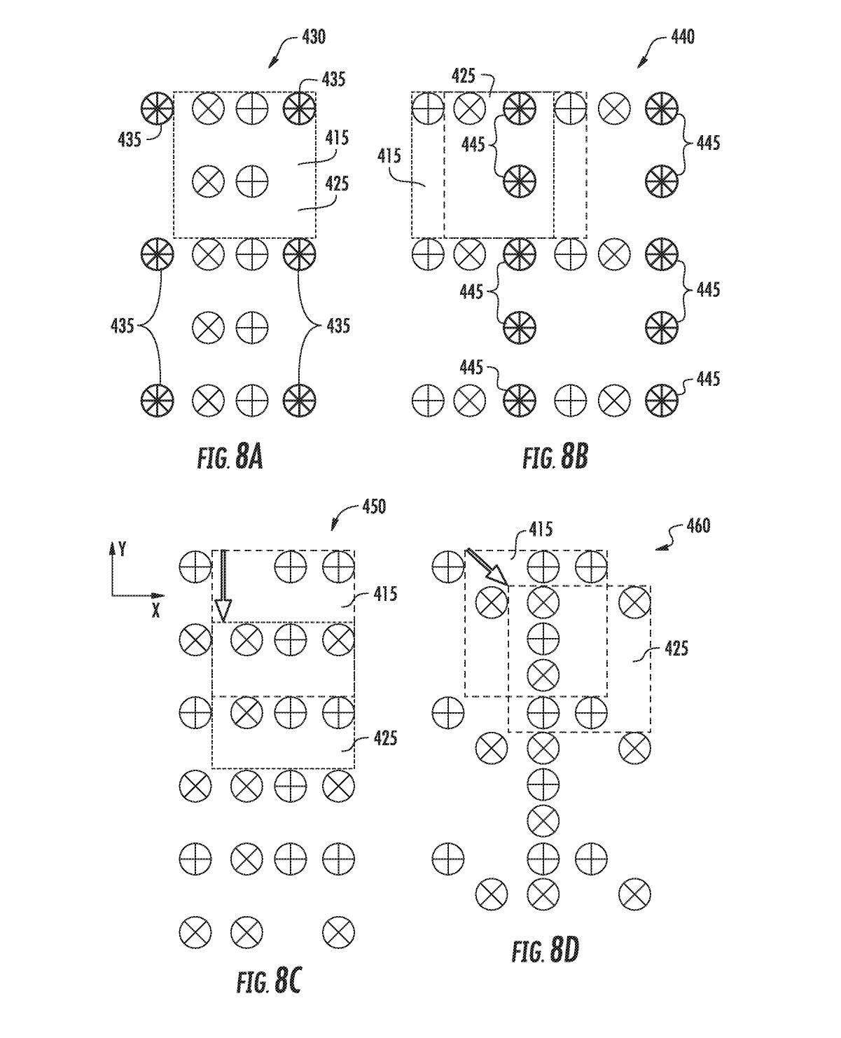

FIGS. 8A-8D depict the example generation of sparse composite grid patterns, dense composite grid patterns, and/or dual grid composite grid patterns by shifting cells 415 and 425 of FIG. 6 relative to one another according to example embodiments of the present disclosure. More particularly, FIG. 8A depicts a sparse grid pattern 430 that can be implemented using a variable pattern separation grid. As shown, the first grid plate and the second grid plate are positioned such that cells 415 and 425 overlap. This can generate the sparse grid pattern 430 having holes 435 where holes in the first grid plate and the second grid plate overlap. The holes 435 are shaded darker relative to the other holes to indicate where the holes in the first grid plate and the second grid plate match up or overlap.

As shown in FIG. 8B, the variable pattern separation grid can be controlled to generate a dense grid pattern 440 by moving the first and/or second grid plate relative to one another so that the second cell 425 is shifted a ⅓ step (e.g., ⅓ the length of the cell) in the x-direction relative to the first cell 415. This will generate a dense grid pattern 440 having holes 445 where holes in the first grid plate and holes in the second grid plate overlap. As depicted in FIG. 8B, the number of holes 445 in the dense composite grid pattern 440 is greater than the number of holes 435 in the sparse composite grid pattern 430.

As shown in FIG. 8C, the variable pattern separation grid can be controlled to generate a dual grid pattern 450 by moving the first and/or second grid plate relative to one another so that the second cell 425 is shifted a ½ step (e.g., ½ the length of the cell) in the negative y-direction relative to the first cell 415. This generates a dual grid pattern 450 where no holes overlap between the first grid plate and the second grid plate.

Similarly, as shown in FIG. 8D, the variable pattern separation grid can be controlled to generate another dual grid pattern 460 by moving the first and/or second grid plate relative to one another so that the second cell 425 is shifted a ⅓ step (e.g., ⅓ the length of the cell) in the x-direction and a ¼ step (e.g., ¼ the length of the cell) in the negative y-direction relative to the first cell 415. This generates a different dual grid pattern 460 where no holes overlap between the first grid plate and the second grid plate.

In some embodiments, each of the grid plates in the variable pattern separation grid can have a grid pattern with different hole densities at different portions of the grid plate. For instance, each of the grid plates can include a first portion that is relatively dense and a second portion that is relatively sparse. The grid plates can be shifted relative to one another to generate a grid patterns of varying densities and/or uniform or nearly uniform grid patterns. For instance, in one embodiment, the grid plates can be shifted relative to one another such that a first portion (e.g., a center portion) of the variable pattern separation grid switches from relatively sparse to relatively dense and a second portion (e.g., a peripheral portion) of the variable pattern separation grid switches from relatively dense to relatively sparse, and vice versa.

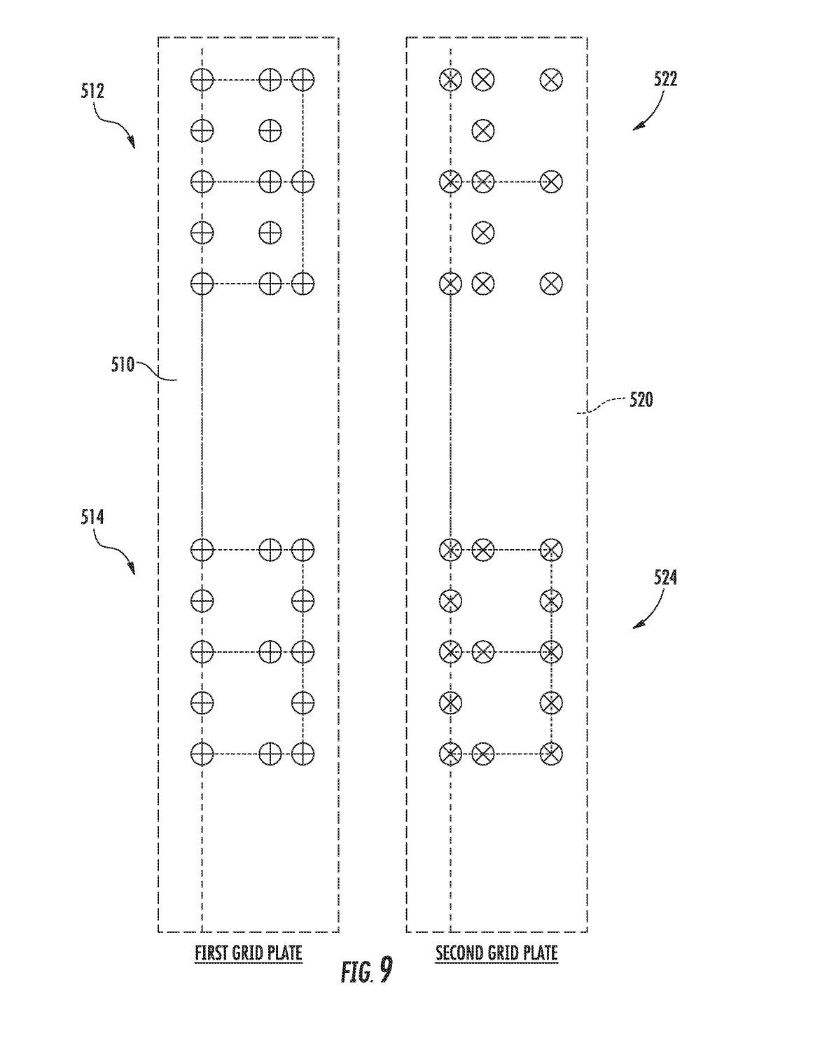

For example, FIG. 9 depicts an example first grid plate 510 and a second grid plate 520. The first grid plate 510 has a first grid pattern 512 in a first portion of the first grid plate 510 and a second grid pattern 514 in a second portion of the first grid plate 510. The first grid pattern 512 is different from the second grid pattern 514. For instance, the first grid pattern 512. The second grid plate 520 has a first grid pattern 522 in a first portion of the second grid plate 520 and a second grid pattern 524 in a second portion of the second grid plate 520. The first grid pattern 522 is different from the second grid pattern 524.

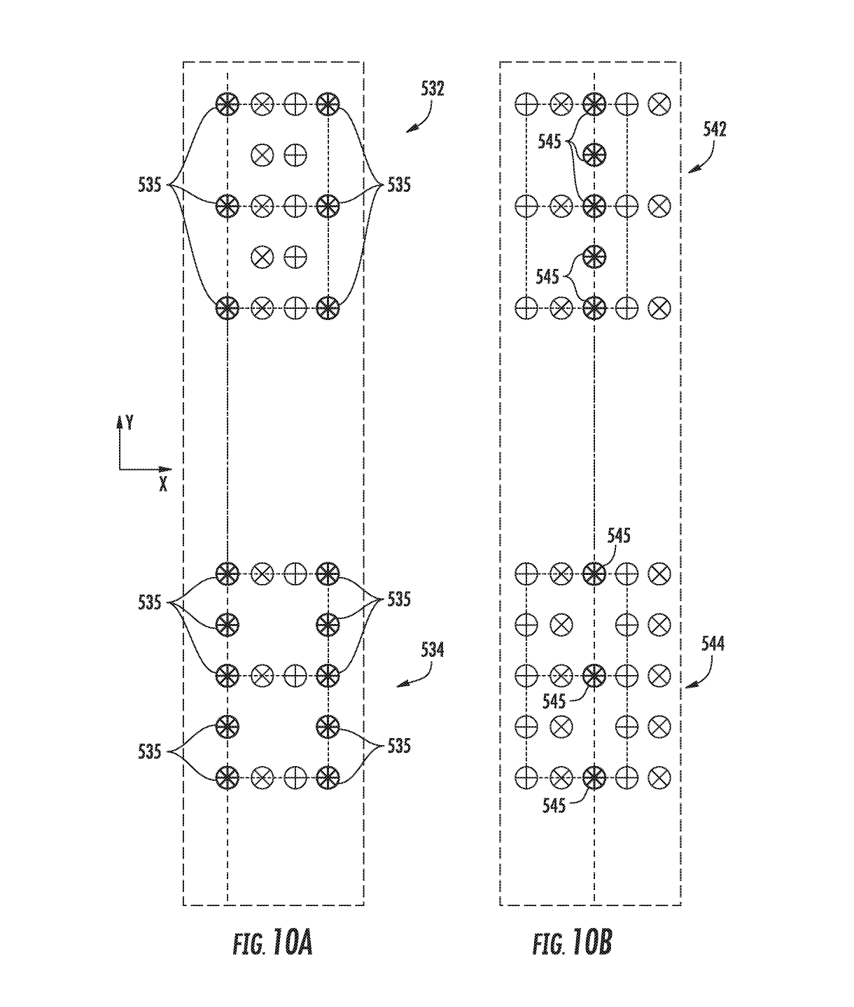

FIG. 10A, shows a grid pattern of the variable pattern separation grid when the first grid plate 510 and the second grid plate 520 are in a first position relative to one another. As shown, the variable pattern separation grid includes a first grid pattern 532 at a first portion of the variable pattern separation grid (e.g., a center portion) that is relatively sparse. The first grid pattern 532 includes holes 535 where holes in the first grid plate 510 and the second grid plate 520 overlap. The variable pattern separation grid further includes a second grid pattern 534 at a second portion of the variable pattern separation grid (e.g., a peripheral portion) that is relatively dense. The second grid pattern 534 includes holes 535 where holes in the first grid plate 510 and the second grid plate 520 overlap.

FIG. 10B shows a grid pattern of the variable pattern separation grid when the first grid plate 510 and/or the second grid plate 520 have been relative to one another in the x-direction. As shown in FIG. 10B, this creates a different grid pattern for the variable pattern separation grid. The different grid pattern includes a first portion 542 at a first portion of the variable pattern separation grid (e.g., a center portion) that is relatively dense. The first grid pattern 542 includes holes 545 where holes in the first grid plate 510 and the second grid plate 520 overlap. The variable pattern separation grid further includes a second grid pattern 544 at a second portion of the variable pattern separation grid (e.g., a peripheral portion) that is relatively sparse. The second grid pattern 544 includes holes 545 where holes in the first grid plate 510 and the second grid plate 520 overlap.

Example composite grid patterns are discussed herein for purposes of illustration and discussion. Those of ordinary skill in the art, using the disclosures provided herein, will understand that variable pattern separation grids according to example embodiments of the present disclosure can be used to create a wide variety of composite grid patterns for different process conditions and/or applications without deviating from the scope of the present disclosure.

In some embodiments, the distance between grid plates can be adjusted to play a role in the ability to control the flow profile. For example, if the distance between grid plates is relatively small, then the ratio of grid flow conductivities between dense and rare areas can be close to 2. However, if the distance between grid plates is large then the secondary flow though mismatching holes is not negligible and this ratio will be reduced. Thus, the distance between grid plates can be adjusted to provide for changes from one profile to another or to provide smaller variation of gas flow profile from one zone (e.g., center) to another (e.g., edge). For typical grids used for 300 mm wafer processing, the distance between grid plates can be in the range of range of about 0.5 mm to about 2 mm. For 450 mm wafer processing, grids can be thicker, so the distance between grid can be larger. On the other hand for smaller wafers (e.g., 2 in, 4 in, 6 in, 8 in) one may choose thinner grid and smaller distance between grid plates.

In some embodiments, one or more of the plurality of grid plates can includes holes of variable size across the grid plate. This way one can significantly increase the dynamic range of the edge/center flow ratio, when switching from one flow pattern to another.

In one example embodiment, a method can include receiving a substrate in a processing chamber of a plasma processing apparatus. The method can include adjusting a position of one or more grid plates of a variable pattern separation grid to generate a composite grid pattern and generating a plasma in a plasma chamber of a plasma processing apparatus. The position of the one or more grid plates can be adjusted based at least in part on a process type for processing the substrate and/or to obtain a desired process profile across the surface of the substrate.

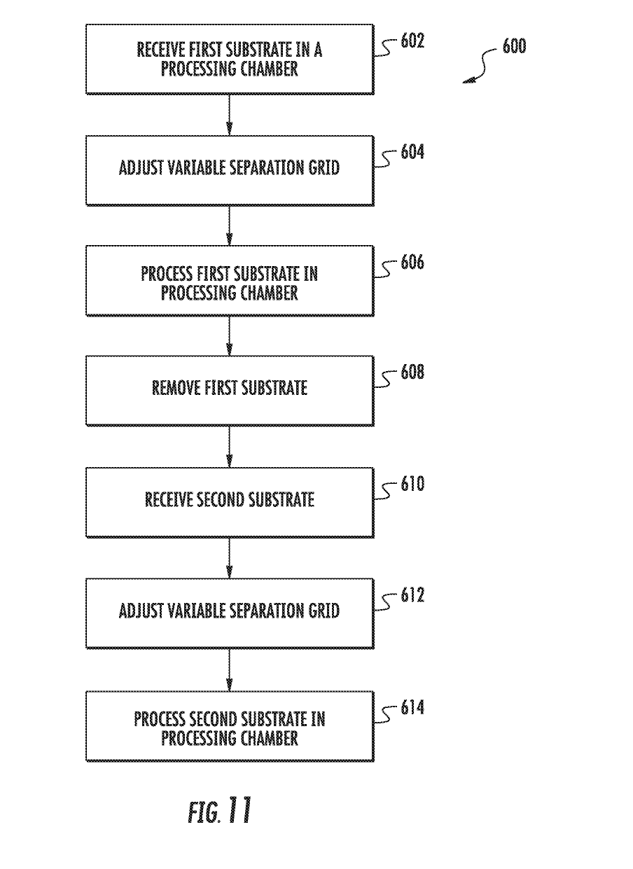

For example, FIG. 11 depicts a flow diagram of an example method (600) of processing a substrate in a plasma processing apparatus according to example embodiments of the present disclosure. FIG. 11 can be implemented, for instance, using the plasma processing apparatus 100 depicted in FIG. 2. In addition, FIG. 11 depicts steps performed in a particular order for purposes of illustration and discussion. Those of ordinary skill in the art, using the disclosures provided herein, will understand that various steps of any of the methods disclosed herein can be adapted, modified, rearranged, performed simultaneously, omitted, and/or expanded in various ways without deviating from the scope of the present disclosure.

At (602), the method can include receiving a first substrate in a processing chamber of a plasma processing apparatus. The processing chamber can be separated from a plasma chamber by a separation grid. The separation grid can be a variable separation grid having a plurality of grid plates. The grid plates can be moved relative to one another to create composite grid patterns according to example embodiments of the present disclosure. The first substrate can be placed into the processing chamber, for instance, using a robot or other suitable substrate transfer mechanism.

At (604), the method can include adjusting the variable separation grid. For instance, a grid plate can be moved relative to another grid plate in the separation grid to create a desired composite grid pattern. The composite grid pattern can be selected based on a desired process type for the first substrate and/or based at least in part on a desired process profile for the first substrate. In some embodiments, the variable separate grid can be adjusted from a first composite grid pattern to a second composite grid pattern. In some embodiments, the first composite grid pattern can be a sparse grid pattern and the second composite grid pattern can be a dense grid pattern, or vice versa. In some embodiments, the second composite grid pattern can be a dual grid pattern. Other suitable composite grid patterns can be used as described herein.

At (606), the method can include processing the first substrate in the processing chamber. For instance, neutrals can pass from the plasma chamber through the separation grid to the processing chamber to process the first substrate. The first substrate can be processed according to a first process type and/or according to a first process profile across the substrate.

At (608), the method can include removing the first substrate from the process chamber. For instance, a robot or other substrate transfer mechanism can be used to transfer the first substrate out of the processing chamber.

At (610), the method can include receiving a second substrate. The second substrate can be placed into the processing chamber, for instance, by a robot or other substrate transfer mechanism. According to example embodiments of the present disclosure, the second substrate can be placed into the processing chamber without requiring opening of the plasma processing apparatus for changing out of the separation grid, even though the second substrate may be processed using a different process type and/or process profile relative to the first substrate.

At (612), the method can include adjusting the variable separation grid. For instance, a grid plate can be moved relative to another grid plate in the separation grid to create a desired composite grid pattern. The composite grid pattern can be selected based on a desired process type for the second substrate and/or based at least in part on a desired process profile for the second substrate. In some embodiments, the variable separate grid can be adjusted from a second composite grid pattern to the first composite grid pattern. In some embodiments, the first composite grid pattern can be a sparse grid pattern and the second composite grid pattern can be a dense grid pattern, or vice versa. In some embodiments, the second composite grid pattern can be a dual grid pattern. Other suitable composite grid patterns can be used as described herein.

At (614), the method can include processing the second substrate in the processing chamber. For instance, neutrals can pass from the plasma chamber through the separation grid to the processing chamber to process the second substrate. The first substrate can be processed according to a second process type and/or according to a second process profile across the substrate. The second process type can be different from the first process type. The second process profile can be different from the first process profile.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus comprising:
a plasma chamber;
a processing chamber separated from the plasma chamber;
a variable pattern separation grid separating the plasma chamber and the processing chamber, the variable pattern separation grid comprising a plurality grid plates, each grid plate having a grid pattern with one or more holes;
wherein at least one of the grid plates is movable relative to another grid plate in the plurality of grid plates such that the variable pattern separation grid can provide a plurality of different composite grid patterns.

2. The plasma processing apparatus of claim 1, wherein the plurality of different composite grid patterns comprise one or more of a sparse composite grid pattern, a dense composite grid pattern, and/or a dual grid composite grid pattern.

3. The plasma processing apparatus of claim 1, wherein the plurality of grid plates comprise a first grid plate and a second grid plate, the second grid plate being movable relative to the first grid plate.

4. The plasma processing apparatus of claim 3, wherein when the second grid plate is in a first position, the variable pattern separation grid provides a first composite grid pattern, wherein when the second grid plate is in a second position, the variable pattern separation grid provides a second composite grid pattern.

5. The plasma processing apparatus of claim 4, wherein the first composite grid pattern has a first hole density and the second composite grid pattern has a second hole density that is different than the first hole density.

6. The plasma processing apparatus of claim 4, wherein the second composite grid pattern is a dual grid composite grid pattern configured to block UV light.

7. The plasma processing apparatus of claim 4, wherein in the first composite grid pattern, a first portion of the variable pattern separation grid has a first hole density and a second portion of the variable pattern separation grid has a second hole density, the second hole density being different from the first hole density.

8. The plasma processing apparatus of claim 4, wherein in the second composite grid pattern, the first portion of the variable pattern separation grid has a third hole density that is different from the first hole density and the second portion of the variable pattern separation grid has a fourth hole density that is different from the second hole density.

9. The plasma processing apparatus of claim 3, wherein the second grid plate is movable relative to a first grid plate in one or more of three-dimensions.

10. The plasma processing apparatus of claim 3, wherein the second grid plate is coupled to a manipulator configured to move the second grid plate relative to the first grid plate.

11. The plasma processing apparatus of claim 3, wherein one or more of the first grid plate and the second grid plate are electrically conductive.

12. The plasma processing apparatus of claim 3, wherein one or more of the first grid plate and the second grid plate are grounded.

13. A separation grid for a plasma processing apparatus, the separation grid comprising:
a first grid plate having a first grid pattern;
a second grid plate in spaced parallel relationship with the first grid plate, the second grid plate having a second grid pattern,
wherein the second grid plate being movable relative to the first grid plate such that when the second grid plate is in a first position relative to the first grid plate, the separation grid provides a first composite grid pattern and when the second grid plate is in a second position, the separation grid provides a second composite grid pattern, the second composite grid pattern being different than the first composite grid pattern.

14. The separation grid of claim 13, wherein the first composite grid pattern is a sparse composite grid pattern and the second composite grid pattern is a dense composite grid pattern that has greater hole density relative to the sparse composite grid pattern.

15. The separation grid of claim 13, wherein the second composite grid pattern is a dual grid composite grid pattern for blocking UV light.

16. The separation grid of claim 13, wherein in the first composite grid pattern, a first portion of the variable pattern separation grid has a first hole density and a second portion of the variable pattern separation grid has a second hole density, the second hole density being different from the first hole density.

17. The separation grid of claim 16, wherein in the second composite grid pattern, the first portion of the variable pattern separation grid has a third hole density that is different from the first hole density and the second portion of the variable pattern separation grid has a fourth hole density that is different from the second hole density.

18. A method of processing a substrate in a plasma processing apparatus, comprising:
receiving a first substrate in a processing chamber, the processing chamber being separated from a plasma chamber by a variable pattern separation grid, the variable pattern separation grid comprising a first grid plate having a first grid pattern and a second grid plate in spaced parallel relationship with the first grid plate, the second grid plate having a second grid pattern;
adjusting a position of the second grid plate relative to the first grid plate to adjust a composite grid pattern associated with the variable pattern separation grid from a first composite grid pattern to a second composite grid pattern, the second composite grid pattern being different from the first composite grid pattern; and
processing the first substrate in the processing chamber using neutral species passing from the plasma chamber to the processing chamber through the variable pattern separation grid.

19. The method of claim 18, wherein the method comprises:
receiving a second substrate in the processing chamber;
adjusting a position of the second grid plate relative to the first grid plate to adjust the composite grid pattern associated with the variable pattern separation grid from the second composite grid pattern to the first composite grid pattern; and
processing the second substrate in the processing chamber using neutral species passing from the plasma chamber to the processing chamber through the variable pattern separation grid.

20. The method of claim 18, wherein the first composite grid pattern is a sparse composite grid pattern and the second composite grid pattern is a dense composite grid pattern that has greater hole density relative to the sparse composite grid pattern.
